(19) United States
(12) Patent Application Publication
(10) Pub. No.: US 2026/0314096 A1
(43) Pub. Date: Oct. 8, 2026

(54) IMAGE SENSING DEVICE AND PHOTOGRAPHING SYSTEM INCLUDING THE SAME

(71) Applicant: SK hynix Inc., Icheon-si (KR)

(72) Inventor: Jong Chae KIM, Icheon-si (KR)

(21) Appl. No.: 19/290,903

(22) Filed: Aug. 5, 2025

(30) Foreign Application Priority Data
Apr. 8, 2025 (KR) 10-2025-0045621

(51) Int. Cl. H10F 39/00; G01S 7/481; G01S 7/4865; G01S 17/894; H10F 39/18

(52) U.S. Cl. CPC H10F 39/806; G01S 7/4816; G01S 7/4865; G01S 17/894; H10F 39/184

(57) ABSTRACT

In one embodiment of the disclosed technology, an image sensing device includes a circuit layer, a photodetector including an active area configured to detect light and disposed on the circuit layer, and a substrate layer on the photodetector, wherein the substrate layer includes a trench that is recessed in a thickness direction of the substrate layer and surrounds an active area in a plan view.

### CROSS REFERENCE TO RELATED APPLICATION

This patent document claims the priority and benefits of Korean Patent Application No. 10-2025-0045621, filed Apr. 8, 2025, the entire contents of which are incorporated herein by reference for all purposes.

### TECHNICAL FIELD

The disclosed technology relates to an image sensing device and an imaging system including the same.

### BACKGROUND

Recently, time of flight (TOF) technology has been gaining significant attention. The TOF technology measures the distance between a sensor and a target object by sending pulse-shaped light toward the target object from a light source disposed inside or near a sensor, and receiving the light reflected from the target object, and measuring the time interval between the time of light emission at the light source and the time of reception of reflected light from the target object. The TOF method uses the above TOF measurements to calculate the distance between the sensor and the target object based on the constant speed of light.

To ensure accurate TOF measurement, an immediate reaction is required when a light-receiving element detects the reflected light. Therefore, a highly sensitive photoelectric conversion element is desirable. To this end, research on single photon avalanche diodes (SPADs), which can be manufactured using CMOS process technology, is actively underway.

### SUMMARY

The disclosed technology can be implemented in some embodiments to provide an image sensing device and an imaging system designed to increase an absorption rate of light incident on a single photon avalanche diode (SPAD).

The disclosed technology can be implemented in some embodiments to provide an image sensing device and an imaging system designed to minimize surface reflection from an SPAD.

The disclosed technology can be implemented in some embodiments to provide an image sensing device and an imaging system designed to decrease a reflection rate of an upper portion of an SPAD, thereby increasing a light transmittance.

In one embodiment of the disclosed technology, an image sensing device may include a circuit layer, a photodetector including an active area configured to detect light and disposed on the circuit layer, and a substrate layer on the photodetector, wherein the substrate layer includes a trench that is recessed in a thickness direction of the substrate layer and surrounds an active area in a plan view.

In another embodiment of the disclosed technology, an imaging system may include a light source configured to emit light toward a target object, and a pixel array including: a pixel area configured to receive light reflected from the target object and includes an active area, and a non-pixel area around the pixel area, wherein the pixel array includes a circuit layer, a photodetector disposed on the circuit layer, and a substrate layer disposed on the photodetector, wherein the substrate layer includes a trench surrounding the active area, a deep trench in the non-pixel area, the deep trench having a greater recess depth than the trench surrounding the active area, and a recessed structure inside the trench or between the deep trench and the trench, and wherein the trench, the deep trench, and the recessed structure have different recess depths.

In some embodiments of the disclosed technology, it is possible to increase the absorption rate of the amount of light incident on the single photon avalanche diode (SPAD).

In this way, it is possible to minimize surface reflection of the SPAD.

In addition, it is possible to decrease the reflection rate of the upper portion of the SPAD, thereby increasing the light transmittance.

However, the advantages and effects associated with some embodiments described in this patent document are not limited to those described above, and other advantages, effects, and features will become apparent from the following description.

### BRIEF DESCRIPTION OF THE DRAWINGS

FIG. 1 is a block diagram illustrating an imaging system based on one embodiment.

FIG. 2 is a plan view of a pixel array based on one embodiment.

FIG. 3 is an enlarged plan view of area Q1 in FIG. 2.

FIG. 4 is a cross-sectional view along line A-A′ in FIG. 3.

FIG. 5 is a schematic view illustrating an optical path of incident light incident on one pixel.

FIG. 6 is a cross-sectional view of one pixel based on another embodiment.

FIG. 7 is an enlarged view of a pixel array based on another embodiment.

### DETAILED DESCRIPTION

Hereinafter, embodiments will be described with reference to the accompanying drawings.

The same reference numerals indicate the same components. In addition, in the drawings, thicknesses, proportions, and dimensions of components are exaggerated for effective description of technical contents. The term “and/or” includes any one or more combinations that may be defined by the associated configurations.

Terms such as “first” and “second” may be used to describe various components, but the components are not limited by the terms. The terms are used to distinguish one component from another. For example, a “first” component may be referred to as a “second” component, and similarly, the “second” component may also be referred to as the “first” component without departing from the scopes of the embodiments.

The disclosed technology can be implemented in some embodiments to provide a pixel structure (e.g., SPAD) designed to maximize light absorption efficiency, especially for weak signals returning from distant objects. This can be achieved, among other structures and methods, through a trenched light guiding structure that can improve internal light propagation and reducing loss.

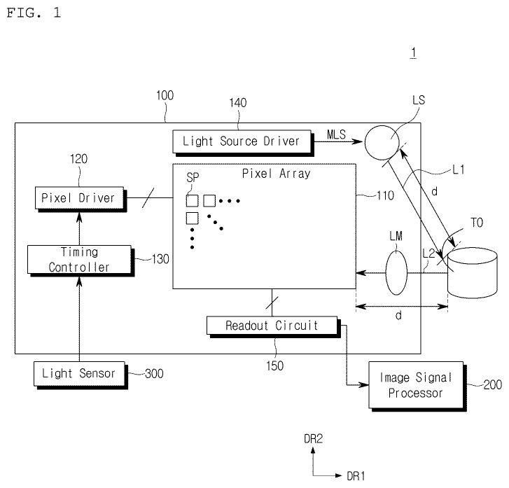

FIG. 1 is a block diagram illustrating an imaging system based on one embodiment.

Referring to FIG. 1, the imaging system 1 may be an imaging device such as a digital still camera that captures still images or a digital video camera that captures moving images. For example, the imaging system 1 may be implemented as a digital single lens reflex (DSLR) camera, a mirrorless camera, or a mobile phone (e.g., a smartphone) or other portable or non-portable devices or systems with imaging functions, but is not limited thereto. The imaging system 1 may be a concept that includes a device that may capture an image of a subject and generate an image by including a lens and an imaging element.

The imaging system 1 may include an image sensing device 100 for capturing still images or video images and an image signal processor 200 for processing the captured imaging data by the imaging sending device 100.

The image sensing device 100 may measure a distance using the time of flight (TOF) principle. The image sensing device 100 may include a light-condensing pattern or an optical device LM (e.g., an optical lens or other light condensing or focusing device) for collecting and directing light from the target object TO, a pixel array 110 with an array of pixels for receiving and detecting collected light from the target object TO, a pixel driver 120 for driving the sensing pixels in the pixel array 110, a timing controller 130 coupled to the pixel driver 120, a light source LS for emitting light L1 towards the target object TO, a light source driver 140 for controlling the light emission of the light source LS, and a readout circuit 150 coupled to the pixel array 110 for reading out pixel signals from the pixels of the pixel array 110. The imaging system 1 based on one embodiment may further include a light sensor 300. The light sensor 300 may sense the illuminance of the surrounding environment, determine whether the sensed illuminance is greater than or equal to a reference illuminance or less than the reference illuminance, and transmit the determined result to the timing controller 130.

The light source LS may emit light L1 to a target object TO in response to a reference pulse signal MLS from the light source driver 140. The light source LS may be or include, in some implementations, a laser diode (LD) or a light-emitting diode (LED) emitting light of a specific wavelength band (e.g., infrared or visible light), a near-infrared (NIR) laser, a point light source, a white lamp, a monochromatic light source combined with a monochromator, or a combination of another laser source (LS). For example, the light source LS may emit infrared light having a wavelength of about 800 nm to about 1000 nm. FIG. 1 illustrates only one light source LS for convenience of description, but a plurality of light sources LS may be arranged around the light-condensing pattern/optical device LM. In one embodiment, the light source LS may include a near infrared laser light source (e.g., vertical cavity surface emitting laser (VCSEL)) including a point light source, but the disclosed technology are not limited thereto.

The light-condensing pattern/optical device LM may receive and condense or focus the light L2 reflected from a target object TO and focus the light L2 on pixels SP of the pixel array 110. The light-condensing pattern/optical device LM may include a focusing lens or another cylindrical optical element on a surface of glass or plastic. The light-condensing pattern/optical device LM may include one lens group composed of at least one lens. The light collecting/condensing pattern/optical device LM may be a microlens, but the disclosed technology are not limited thereto.

The pixel array 110 may include a plurality of pixels SP arranged continuously in a two-dimensional matrix structure. That is, the pixel array 110 may include the plurality of pixels SP arranged continuously in a first direction DR1 and a second direction DR2. Each pixel SP may include a pixel area. Each pixel SP may photoelectrically convert incident light (e.g., reflected light L2 that is reflected from a target object) received through the light collecting/condensing pattern/optical device LM and generate and output a pixel signal that is an electric signal corresponding to the incident light. In this case, the pixel signal may be a signal representing information corresponding to a distance to the target object TO rather than a signal representing a color of the target object TO. Each of the plurality of pixels SP may include a single photon avalanche diode (SPAD).

The pixel array 110 in which the plurality of pixels SP are arranged may detect the distance to the target object TO using a direct TOF method. For reference, the direct TOF method is a method of calculating the distance to the target object TO by directly measuring the round-trip time from the time when the pulse light is emitted to the target object TO to the time when the pulse light is reflected back from the target object TO and calculating the round-trip time and the speed of light. However, the disclosed technology are not limited thereto, and the pixel array 110 in which the plurality of pixels SP are arranged may detect the distance to the target object TO using an indirect TOF method.

The pixel driver 120 may drive the pixel array 110 under the control of the timing controller 130. For example, the pixel driver 120 may generate a quenching control signal to control the quenching operation of reducing a reverse bias voltage applied to the pixel SP to a breakdown voltage or less. That is, the pixel driver 120 may control the turn-on/turn-off of the pixel SP under the control of the timing controller 130.

The readout circuit 150 may be disposed on one side of the pixel array 110, may calculate the time delay between the pulse signal (or the pixel signal) output from each pixel SP and a reference pulse, and generate and store digital data (or pixel data) corresponding to the time delay. The readout circuit 150 may transmit the stored digital data to the image signal processor 200 under the control of the timing controller 130.

The timing controller 130 may control the overall operation of the image sensing device 100. That is, the timing controller 130 may generate timing signals for controlling the operation of the pixel driver 120 and the light source driver 140. In addition, the timing controller 130 may control the activation or deactivation of the readout circuit 150 and control the digital data stored in each of the readout circuits 150 to be transmitted simultaneously or sequentially to the image signal processor 200.

The light source driver 140 may generate a clock signal that may drive the light source LS under the control of the timing controller 130.

The image signal processor 200 may process the digital data (or the pixel data) input from the image sensing device 100 and generate a depth image (in the form of a histogram) representing the distance to the target object TO. Specifically, the image signal processor 200 may calculate the distance to the target object TO for each pixel based on the time delay represented by the digital data received from the readout circuit 150.

The image signal processor 200 may control the operation of the image sensing device 100. In some implementations, the image signal processor 200 may analyze the digital data input from the image sensing device 100 to determine a mode of the image sensing device 100 and control the image sensing device 100 to operate in the determined mode.

The image signal processor 200 may perform image signal processing on the generated depth image to reduce or remove noise and enhance image quality. The depth image output from the image signal processor 200 may be stored in an internal memory or external memory of the imaging system 1, or of a device equipped with the imaging system 1, either automatically or in response to a user's request. The depth image may be displayed through a display device. In some implementations, the depth image output from the image signal processor 200 may be used to control the operation of the imaging system 1 or the device equipped with the imaging system 1.

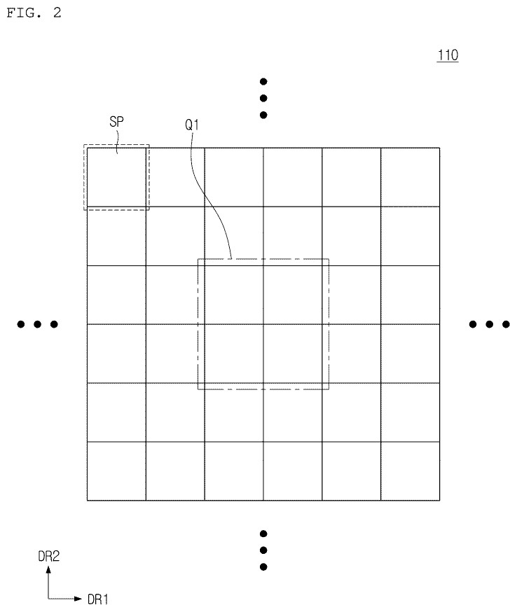

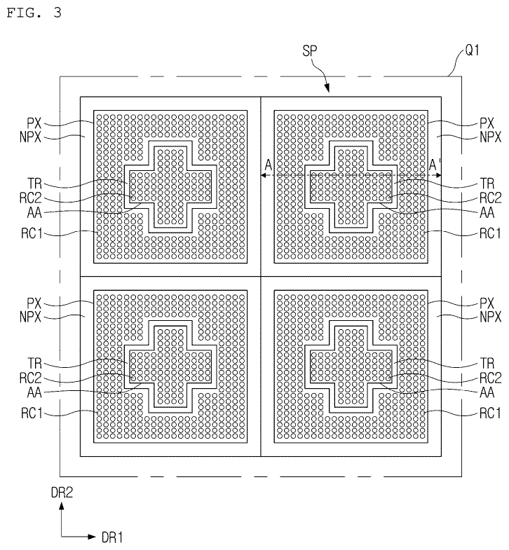

FIG. 2 is a plan view of a pixel array based on one embodiment. FIG. 3 is an enlarged plan view of area Q1 in FIG. 2.

Referring to FIGS. 2 and 3, the pixel array 110 may include a plurality of pixels SP, and each pixel SP may include a pixel area PX and a non-pixel area NPX.

The pixel area PX may be an area that receives external light and converts the received external light into an electrical signal. The pixel area PX may be disposed in each pixel SP. The pixel area PX disposed in each pixel SP may be disposed separately. A photodetector SPAD may be disposed in the pixel area PX. The pixel area PX may be substantially the same as an area in which the photodetector SPAD is disposed, but is not limited thereto.

The non-pixel area NPX may be an area that does not receive external light or does not convert light into an electrical signal even when receiving light. For example, in some implementations, the non-pixel area NPX may be structured without having an operational optical sensing function. The non-pixel area NPX may be disposed around the pixel area PX. The non-pixel area NPX may be disposed between the pixel areas PX of adjacent pixels SP. The non-pixel area NPX may be disposed to surround the pixel area PX, but is not limited thereto.

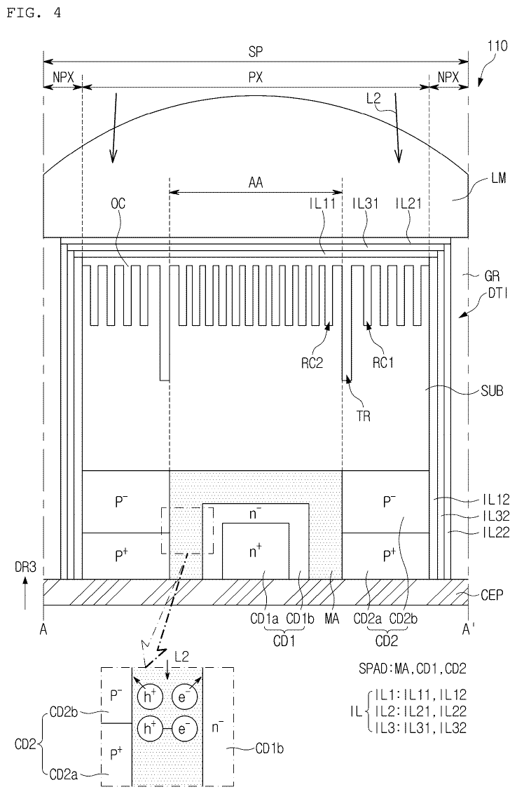

Each pixel SP may include an optically active area AA. The optically active area AA may be arranged within the pixel area PX. In some implementations, the optically active area refers to the region where light is detected and converted into electrical signals. As shown in FIG. 4, in some embodiments, the active area AA may be an area in which a first semiconductor area CD1 (see FIG. 4) is located.

The first semiconductor area CD1 (see FIG. 4) may be located in the active area AA, and a second semiconductor area CD2 (see FIG. 4) may be located outside the active area AA. The first semiconductor area CD1 (see FIG. 4) and the second semiconductor area CD2 (see FIG. 4) may be located in the pixel area PX.

In some implementations, the active area AA may be defined by the photodetector SPAD. In some implementations, the photodetector SPAD may include the active area AA.

In some embodiments, the active area AA may be formed in an island shape in a plan view, but is not limited thereto. The active area AA may be formed such that an area extending in the first direction DR1 intersects an area extending in the second direction DR2 in a plan view, but is not limited thereto. The active area AA may have a “+” shape in a plan view, but is not limited thereto.

Each pixel SP may include a trench TR, a first recessed structure RC1, and a second recessed structure RC2.

Each of the first recessed structure RC1 and the second recessed structure RC2 may be formed in a circular shape in a plan view, but is not limited thereto. For example, each of the first recessed structure RC1 and the second recessed structure RC2 may be formed in an oval shape or formed in a polygonal shape, such as a triangle, a quadrangle, a pentagon, or the like, in a plan view.

The trench TR in a plan view may be disposed around the active area AA. The trench TR in a plan view may be disposed to surround the active area AA. However, the disclosed technology are not limited thereto, and the trench TR may be disposed in the active area AA and disposed along an edge of the active area AA.

Each of the first recessed structure RC1 and the second recessed structure RC2 may include a plurality of recessed structures. The plurality of first recessed structures RC1 and the plurality of second recessed structures RC2 may be disposed in the pixel area PX. The plurality of first recessed structures RC1 may be disposed outside the active area AA, and the plurality of second recessed structures RC2 may be disposed inside the active area AA.

The plurality of first recessed structures RC1 may be disposed outside the trench TR, and the plurality of second recessed structures RC2 may be surrounded by the trench TR.

The plurality of first recessed structures RC1 may overlap the second semiconductor area CD2 in a thickness direction (e.g., a third direction DR3), and the plurality of second recessed structures RC2 may overlap the first semiconductor area CD1 in the thickness direction (e.g., the third direction DR3).

A cross-sectional structure of each pixel SP will be described with reference to FIG. 4.

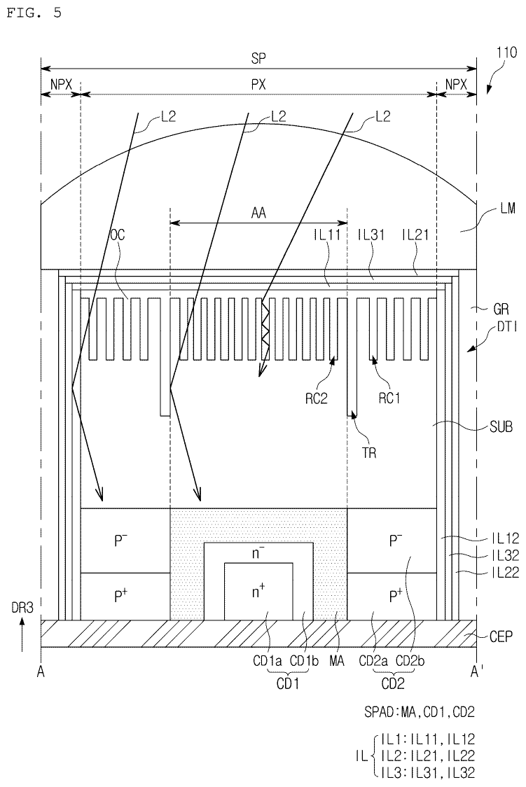

FIG. 4 is a cross-sectional view along line A-A′ in FIG. 3. FIG. 5 is a schematic view illustrating an optical path of incident light incident on one pixel.

Referring to FIGS. 3 to 5, the pixel array 110 based on one embodiment may include a circuit layer CEP and the photodetector on the circuit layer CEP. The photodetector for the pixel SP of the pixel array 110 may include a single photon avalanche diode (SPAD). The pixel array 110 based on one embodiment may include a substrate layer SUB on the photodetector SPAD, a deep trench DTI outside the photodetector SPAD, the trench TR disposed in the pixel area PX, the first recessed structure RC1 and the second recessed structure RC2, a planarization layer OC on the substrate layer SUB, an insulating layer IL on the planarization layer OC, a filling part GR disposed in the deep trench DTI, and a light-condensing pattern/optical device LM on the insulating layer IL.

The circuit layer CEP may be disposed on a lower surface of the photodetector SPAD and may include transistors, interconnect layers, and interlayer insulating layers. The transistors may include an analog quenching transistor, a readout transistor, and the like that are formed on the lower surface of the photodetector SPAD.

The photodetector SPAD may include the first semiconductor area CD1, the second semiconductor area CD2, an intermediate area MA between the first semiconductor area CD1 and the second semiconductor area CD2.

The first semiconductor area CD1 may be an n-type semiconductor area, and the second semiconductor area CD2 may be a p-type semiconductor area. For example, p-type ions may include boron (B) ions, and n-type ions may include phosphorous (P) and/or arsenic (As) ions. For example, the first semiconductor area CD1 may include a 1-1 semiconductor area CD1a that is an n+-type semiconductor area on the circuit layer CEP, and a 1-2 semiconductor area CD1b that is an n-type semiconductor area on the 1-1 semiconductor area CD1a, and the second semiconductor area CD2 may include a 2-1 semiconductor area CD2a that is a p+-type semiconductor area on the circuit layer CEP, and a 2-2 semiconductor area CD2b that is a p-type semiconductor area on the 2-1 semiconductor area CD2a.

For example, the 1-1 semiconductor area CD1a may have a higher n-type impurity doping concentration than the 1-2 semiconductor area CD1b, and the 2-1 semiconductor area CD2a may have a higher p-type impurity doping concentration than the 2-2 semiconductor area CD2b, but the disclosed technology are not limited thereto, and the 1-1 semiconductor area CD1 and the 2-2 semiconductor area CD2 may include only one n-type and one p-type semiconductor area.

In some embodiments, upper and lower locations of the 1-1 semiconductor area CD1a and the 1-2 semiconductor area CD1b may be changed, and upper and lower locations of the 2-1 semiconductor area CD2a and the 2-2 semiconductor area CD2b may be changed.

The intermediate area MA may be disposed between the 1-1 semiconductor area CD1 and the 2-2 semiconductor area CD2. The intermediate area MA may also be disposed on an upper surface of the first semiconductor area CD1. The mechanism of electrons (e−) and holes (h+) in the intermediate area MA will be described below.

The substrate layer SUB may be disposed on the photodetector SPAD. The substrate layer SUB may be formed of silicon (Si) and/or a silicon (Si) compound, but is not limited thereto.

The substrate layer SUB may include an n-type semiconductor area or a p-type semiconductor area. However, the impurity doping concentration of the substrate layer SUB may be lower than that of each of the first semiconductor area CD1 and the second semiconductor area CD2.

The deep trench DTI may be formed in the non-pixel area NPX of the substrate layer SUB. The deep trench DTI may be formed by recessing (or indenting) the substrate layer SUB in the thickness direction (the third direction DR3). For example, the deep trench DTI may completely pass through the substrate layer SUB from an upper surface to a lower surface in the thickness direction (the third direction DR3).

The deep trench DTI may expose the circuit layer CEP, but is not limited thereto. For example, the deep trench DTI may be recessed such that a part of the substrate layer SUB on the circuit layer CEP remains. The deep trench DTI may be formed through a deep trench process.

The insulating layer IL and the filling part GR may be disposed in the deep trench DTI. The insulating layer IL and the filling part GR may completely fill the deep trench DTI.

A refractive index of the deep trench DTI may, for example, range about 1.4 to about 2.0, but is not limited thereto. The deep trench DTI may serve to totally reflect some of incident light L2 incident on the pixel SP and allow the totally reflected light to travel toward the photodetector SPAD.

The trench TR, the plurality of first recessed structures RC1, and the plurality of second recessed structures RC2 may be formed in the pixel area PX of the substrate layer SUB. The number of plurality of first recessed structures RC1 and the number of plurality of second recessed structures RC2 are not limited to the numbers described in FIGS. 3 and 4. The number of plurality of first recessed structures RC1 and the number of plurality of second recessed structures RC2 may vary depending on the design.

The trench TR, the plurality of first recessed structures RC1, and the plurality of second recessed structures RC2 may be formed by recessing the substrate layer SUB in the thickness direction (the third direction DR3). A depth of the trench TR recessed in the thickness direction (the third direction DR3) may be greater than depths of the plurality of first recessed structures RC1 and the plurality of second recessed structures RC2 recessed in the thickness direction (the third direction DR3).

The depths of the plurality of first recessed structures RC1 and the plurality of second recessed structures RC2 recessed in the thickness direction (the third direction DR3) may be substantially the same, but are not limited thereto. A depth of the deep trench DTI recessed in the thickness direction (the third direction DR3) may be greater than the depth of the trench TR recessed in the thickness direction (the third direction DR3).

The trench TR may serve to totally reflect some of the incident light L2 incident on the pixel SP and allow the totally reflected light to travel toward the photodetector SPAD. Specifically, the trench TR may increase a path of light toward the first semiconductor area CD1 through total reflection. Accordingly, it is possible to further increase the efficiency of the photodetector SPAD.

The plurality of first recessed structures RC1 and the plurality of second recessed structures RC2 may scatter the incident light L2 that is incident from the outside and passes through the light-condensing pattern/optical device LM. As the plurality of first recessed structures RC1 and the plurality of second recessed structures RC2 are disposed, the incident light L2 incident on the pixel SP can be suppressed from being reflected from a surface of the photodetector SPAD, thereby increasing an absorption rate of the amount of light and increasing a light transmittance.

The depth of the trench TR recessed in the thickness direction (the third direction DR3) may range from 2 to 5 times or range from 2 to 10 times the depths of the plurality of first recessed structures RC1 and the plurality of second recessed structures RC2 recessed in the thickness direction (the third direction DR3), but is not limited thereto. When a ratio of the depth of the trench TR recessed in the thickness direction (the third direction DR3) to the depths of the plurality of first recessed structures RC1 and the plurality of second recessed structures RC2 recessed in the thickness direction (the third direction DR3) is within the above range, the trench TR can more smoothly totally reflect the incident light L2, and the first recessed structure RC1 and the second recessed structure RC2 can more smoothly scatter the incident light L2.

The deep trench DTI, the trench TR, the plurality of first recessed structures RC1, and the plurality of second recessed structures RC2 may increase the path of light by scattering the incident light L2 or totally reflecting the light toward the photodetector SPAD. Accordingly, it is possible to increase the photoelectric conversion efficiency of the photodetector SPAD.

The planarization layer OC may fill the trench TR, the plurality of first recessed structures RC1, and the plurality of second recessed structures RC2. The planarization layer OC may be disposed on the substrate layer SUB to fill the trench TR, the plurality of first recessed structures RC1, and the plurality of second recessed structures RC2. That is, the same material may be disposed (filled) in the trench TR, the plurality of first recessed structures RC1, and the plurality of second recessed structures RC2.

The planarization layer OC may include an organic insulation material. Even when the trench TR, the plurality of first recessed structures RC1, the plurality of second recessed structures RC2, and the like are disposed on the lower portion through the planarization layer OC, an upper portion may be planarized. Accordingly, other components can be disposed more smoothly on the planarization layer OC.

A refractive index of the planarization layer OC may have a value between a refractive index of the substrate layer SUB and a refractive index of the insulating layer IL, but is not limited thereto. For example, the refractive index of the planarization layer OC may be less than the refractive index of the substrate layer SUB and more than the refractive index of the insulating layer IL.

The insulating layer IL may be disposed on the planarization layer OC. The insulating layer IL may be disposed not only on the planarization layer OC, but also in the deep trench DTI. At least a part of the insulating layer IL may also be disposed on a sidewall of the deep trench DTI. The refractive index of the insulating layer IL may have a value between a refractive index of the light-condensing pattern/optical device LM and the refractive index of the planarization layer OC.

The deep trench DTI may be filled with a material different from the material filling the trench TR, the first recessed structure RC1, and the second recessed structure RC2.

The insulating layer IL may include at least one insulating layer. For example, the insulating layer IL may include a first insulating layer IL1, a second insulating layer IL2, and a third insulating layer IL3. In the disclosed technology, an example in which the insulating layer IL is formed in three layers is described, but the disclosed technology are not limited thereto and may be formed of one insulating layer, two insulating layers, or four or more insulating layers.

The first insulating layer IL1 may include an 11^{th} insulating layer IL11 disposed on the upper surface of the substrate layer SUB, and a 12^{th} insulating layer IL12 disposed on a side surface (or the deep trench DTI) of the substrate layer SUB. The 11^{th} insulating layer IL11 may be directly disposed on an upper surface of the planarization layer OC, but is not limited thereto.

The second insulating layer IL2 may include a 21^{st} insulating layer IL21 disposed on the 11^{th} insulating layer IL11, and a 22^{nd} insulating layer IL22 disposed on the 12^{th} insulating layer IL12.

The third insulating layer IL3 may include a 31^{st} insulating layer IL31 disposed between the 11^{th} insulating layer IL11 and the 21^{st} insulating layer IL21, and a 32nd insulating layer IL32 disposed between the 12^{th} insulating layer IL12 and the 22^{nd} insulating layer IL22.

The 12^{th} insulating layer IL12, the 32^{nd} insulating layer IL32, and the 22^{nd} insulating layer IL22 may be sequentially disposed on the substrate layer SUB in the deep trench DTI.

FIG. 4 illustrates the 11^{th} insulating layer IL11 and the 12^{th} insulating layer IL12, the 21^{st} insulating layer IL21 and the 22^{nd} insulating layer IL22, and the 31^{st} insulating layer IL31 and the 32^{nd} insulating layer IL32, which are formed as separate layers but are in contact with each other. However, the disclosed technology are not limited thereto. For example, depending on the process, the 11^{th} insulating layer IL11 and the 12^{th} insulating layer IL12 may be formed as a single, integral layer, the 21^{st} insulating layer IL21 and the 22^{nd} insulating layer IL22 may be formed as a single, integral layer, and the 31^{st} insulating layer IL31 and the 32^{nd} insulating layer IL32 may be formed as a single, integral layer.

Generally, light tends to have a high reflectivity at an interface between materials having a large difference in refractive index. As described above, when the refractive index of each component increases sequentially along the path along which the incident light L2 is incident, it is possible to minimize the reflectivity at interfaces of the components and minimize the reflection of the incident light L2 at each interface. Accordingly, it is possible to increase the absorption rate of the incident light L2 of the photodetector SPAD.

The first insulating layer IL1, the second insulating layer IL2, and the third insulating layer IL3 may be disposed in each pixel area PX and each non-pixel area NPX. Specifically, the insulating layer IL may be disposed to extend to the pixel area PX of each pixel SP and the non-pixel area NPX around the pixel area PX.

The first insulating layer IL1 to the third insulating layer IL3 may include at least one of silicon oxide (SiO₂), silicon oxynitride (SiON), silicon nitride (SiNₓ), hafnium oxide (HfO₂), titanium oxide (TiOₓ), etc.

The filling part GR may be disposed in the non-pixel area NPX. For example, the filling part GR may be arranged in a manner of being sandwiched between the insulating layers IL disposed in adjacent pixel areas PX. The filling part GR may come into direct contact with the insulating layers IL disposed in the adjacent pixels SP. For example, the filling part GR may include tungsten (W), but the disclosed technology are not limited thereto.

In some embodiments, the insulating layers IL on the upper surface of the substrate layer SUB have a low reflectivity with respect to the incident light L2 such that the incident light L2 that has passed through the light-condensing pattern/optical device LM is not totally reflected but is incident on the photodetector SPAD.

In some embodiments, the filling part GR may be omitted, and polysilicon may be disposed in the area in which the filling part GR is disposed (e.g., the non-pixel area NPX).

The insulating layers IL on the side surface of the substrate layer SUB may serve to totally reflect a part of the incident light L2 that is incident on the photodetector SPAD and travels toward the non-pixel area NPX. Accordingly, the reflectivity of the insulating layer IL with respect to the incident light L2 is high.

On the upper surface of the substrate layer SUB, the light-condensing pattern/optical device LM may be disposed on the insulating layer IL. The light-condensing pattern/optical device LM may serve to receive externally incident light in each pixel area PX. To this end, the light-condensing pattern/optical device LM may have the shape of a convex lens that is convex upward and may be formed of a material with a large difference in refractive index compared to outside air. For example, the refractive index of the light-condensing pattern/optical device LM may range from about 1.5 to about 1.7, but is not limited thereto.

As illustrated in FIG. 4, the light-condensing pattern/optical device LM may be continuously disposed in the pixel area PX and the non-pixel area NPX and formed such that a convex lens-shaped end portion of the light-condensing pattern/optical device LM is located on a central portion of the pixel area PX to provide improved collection of light and focusing of the collected light onto the photodetector SPAD below the light-condensing pattern/optical device LM. For example, the light-condensing pattern LM may be disconnected from the non-pixel area NPX, and in this case, a plurality of light-condensing patterns/optical devices LM may be located in each pixel area PX for collecting light from the target object TO and directing/focusing collected light to the pixel areas.

The photodetector SPAD may be used as a photoelectric conversion element including a photosensitive P-N junction. That is, the photodetector SPAD may detect a single photon (e.g., a single photon of the incident light L2) reflected by the target object TO (see FIG. 1) and generate pixel data (or a current pulse, a pixel signal, or a pulse signal) corresponding to the detected single photon.

In this case, the pixel data may be generated through a series of processes initiated by avalanche breakdown, which is triggered by the incident single photon in a Geiger mode in which a reverse bias voltage higher than a breakdown voltage is applied between a cathode and an anode.

Here, the avalanche breakdown may occur in the intermediate area MA within the photodetector SPAD. Holes (h+) may be disposed in one area adjacent to the second semiconductor area CD2 of the intermediate area MA, and electrons (e−) may be disposed in the other area adjacent to the first semiconductor area CD1 of the intermediate area MA.

The holes (h+) in one area and the electrons (e−) in the other area may be combined to form electron (e−) and hole (h+) pairs. The electron (e−) and hole (h+) pairs may be impact-ionized by a photon of the incident light L2.

Specifically, when a reverse bias voltage is applied to the photodetector SPAD to increase an electric field, the resulting increase in the electric field induces impact ionization. In this process, electrons (e−) generated by incident photons are accelerated by the strongly applied electric field, generating the electron (e−) and hole (h+) pairs. As the electrons (e−) and holes (h+) generated by the impact ionization phenomenon collide with each other, a large number of carriers may be generated.

Hereinafter, other embodiments of the disclosed technology will be described. For contents that are substantially the same as those described with reference to FIGS. 1 to 5 among components included in other embodiments, the same reference numerals are given, and the overlapping contents may be omitted or briefly described.

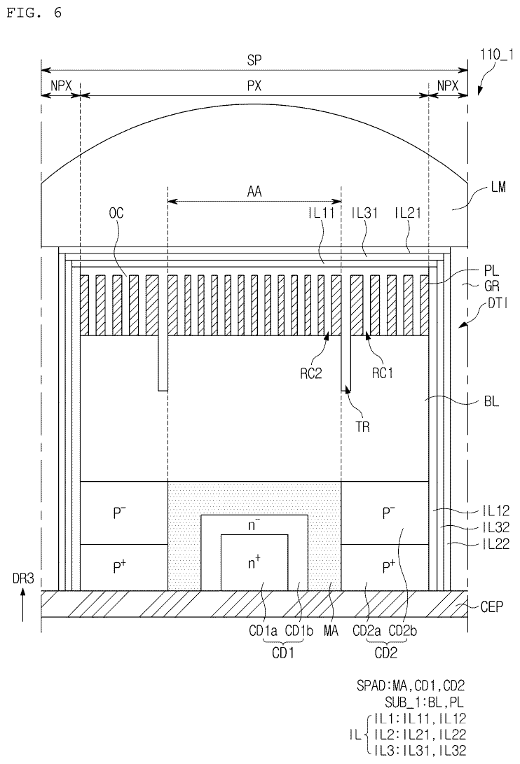

FIG. 6 is a cross-sectional view of one pixel based on another embodiment.

Referring to FIG. 6, a pixel array 110_1 may include a substrate layer SUB_1 defining the deep trench DTI, the trench TR, the first recessed structure RC1, and the second recessed structure RC2. The substrate layer SUB_1 may include a base layer BL and a pattern layer PL that contain different materials.

The base layer BL may be disposed on the semiconductor areas CD1 and CD2. The base layer BL may be disposed between the pattern layer PL and the semiconductor areas CD1 and CD2. The base layer BL may be formed of silicon (Si) and/or a silicon (Si) compound, but is not limited thereto.

The pattern layer PL may be disposed on the base layer BL. The pattern layer PL may be disposed between the base layer BL and the planarization layer OC. The pattern layer PL may define a plurality of first recessed structures RC1 and a plurality of second recessed structures RC2. The plurality of first recessed structures RC1 and the plurality of second recessed structures RC2 may extend through the pattern layer PL in the thickness direction (the third direction DR3). The plurality of first recessed structures RC1 and the plurality of second recessed structures RC2 may expose the base layer BL.

The trench TR may be defined by the base layer BL and the pattern layer PL. That is, the sidewall of the trench TR may be formed of the base layer BL and the pattern layer PL.

The refractive index of the pattern layer PL may have a value between the refractive index of the planarization layer OC and a refractive index of the base layer BL. For example, the refractive index of the pattern layer PL may be more than the refractive index of the planarization layer OC and less than the refractive index of the base layer BL. Accordingly, it is possible to minimize the reflectivity of incident light.

The pattern layer PL may be formed of a different material from the base layer BL. For example, the pattern layer PL may be an area in which the base layer BL is oxidized. Accordingly, when the base layer BL includes silicon (Si), the pattern layer PL may include silicon oxide.

The deep trench DTI may be defined by the base layer BL and the pattern layer PL. That is, the sidewall of the deep trench DTI may be formed of the base layer BL and the pattern layer PL.

Even in this case, the deep trench DTI, the trench TR, the plurality of first recessed structures RC1, and the plurality of second recessed structures RC2 may increase the path of light by scattering the incident light or totally reflecting the light toward the photodetector SPAD. Accordingly, it is possible to increase the photoelectric conversion efficiency of the photodetector SPAD.

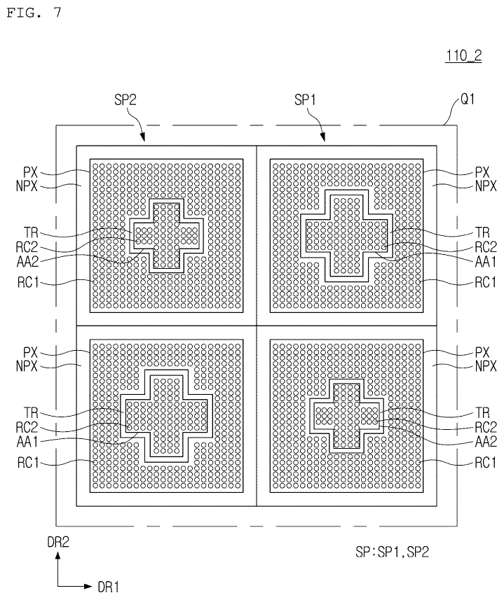

FIG. 7 is an enlarged view of a pixel array based on another embodiment.

Referring to FIG. 7, a pixel array 110_2 may include pixels SP1 and SP2 having active areas AA1 and AA2 of different sizes. A first pixel SP1 may include a first active area AA1, and a second pixel SP2 may include a second active area AA2.

A size (area or width) of the first active area AA1 may be larger than a size of the second active area AA2. The sizes of the active areas AA1 and AA2 and a signal intensity of the photodetector SPAD may be proportional. That is, the larger the sizes of the active areas AA1 and AA2, the greater the signal intensity of the photodetector SPAD.

When the size of the first active area AA1 is larger than that of the second active area AA2, a size (area) of the first semiconductor area CD1 (see FIG. 4) of the first pixel SP1 in a plan view may be larger than a size (area) of the first semiconductor area CD1 (see FIG. 4) of the second pixel SP2 in a plan view.

In this case, the photodetector SPAD of the first pixel SP1 may have higher sensitivity than the photodetector SPAD of the second pixel SP2. That is, the photodetector SPAD of the first pixel SP1 may be a relatively high-sensitivity photodetector SPAD, and the photodetector SPAD of the second pixel SP2 may be a relatively low-sensitivity photodetector SPAD.

The first pixel SP1 and the second pixel SP2 may be alternately and repeatedly disposed in the first direction DR1 and the second direction DR2.

Under the same illuminance conditions and at the same distance from the target object TO (see FIG. 1), the signal intensity of the pixel data generated by the photodetector SPAD of the first pixel SP1 may be greater than the signal intensity of the pixel data generated by the photodetector SPAD of the second pixel SP2.

The imaging system including the pixel array 110_2 based on an embodiment may optionally operate (receive light through the corresponding photodetector SPAD) the high-sensitivity photodetector SPAD and the low-sensitivity photodetector SPAD under different illuminance conditions.

For example, in a low-illuminance environment, a relatively large amount of light needs to be detected, and thus the high-sensitivity photodetector SPAD may be operated. Conversely, in a high-illuminance environment, a relatively small amount of light may be sufficient, and thus the low-sensitivity photodetector SPAD may be used. In some embodiments, the selection between the high-sensitivity or low-sensitivity photodetector SPAD may depend on the distance to the target object TO (see FIG. 1) (light may be detected through the corresponding photodetector SPAD). For example, when the distance is relatively far, the high-sensitivity photodetector SPAD may be operated, and when the distance is relatively close, the low-sensitivity photodetector SPAD may be operated.

By including the photodetectors SPAD with different sensitivities, the distance to the target object can be measured more reliably across various environments.

Even in this case, the deep trench DTI, the trench TR, the plurality of first recessed structures RC1, and the plurality of second recessed structures RC2 may increase the optical path of light by scattering the incident light or totally reflecting the light toward the photodetector SPAD. In this way, it is possible to increase the photoelectric conversion efficiency of the photodetector SPAD.

Only a few implementations and examples of the disclosed technology are described and other implementations, enhancements and variations can be made based on what is described and illustrated in this patent document.

What is claimed is:

1. An image sensing device comprising:
a circuit layer;
a photodetector including an active area configured to detect light and disposed on the circuit layer; and
a substrate layer on the photodetector,
wherein the substrate layer includes a trench that is recessed in a thickness direction of the substrate layer and surrounds an active area in a plan view.

2. The image sensing device of claim 1, further comprising a plurality of first recessed structures and a plurality of second recessed structures that are recessed into the substrate layer in the thickness direction of the substrate layer,
wherein the plurality of first recessed structures are disposed outside the trench in a plan view, and
the plurality of second recessed structures are surrounded by the trench in a plan view.

3. The image sensing device of claim 2, wherein a depth of the trench is greater than depths of the plurality of first recessed structures and the plurality of second recessed structures.

4. The image sensing device of claim 2, wherein the photodetector includes a first semiconductor area and a second semiconductor area disposed around or outside the first semiconductor area, wherein the first semiconductor area is located in the active area of the photodetector.

5. The image sensing device of claim 4, wherein the plurality of first recessed structures overlap the second semiconductor area in the thickness direction, and
the plurality of second recessed structures overlap the first semiconductor area in the thickness direction.

6. The image sensing device of claim 4, wherein the first semiconductor area includes an n+ semiconductor area doped with an n-type dopant at a first concentration and an n-semiconductor area doped with the n-type dopant at a second concentration lower than the first concentration and disposed on the n+ semiconductor area, and
the second semiconductor area includes a p+ semiconductor area doped with a p-type dopant at a third concentration and a p− semiconductor area doped with the p-type dopant at a fourth concentration lower than the third concentration and disposed on the p+ semiconductor area.

7. The image sensing device of claim 4, wherein the photodetector further includes an intermediate area disposed between the first semiconductor area and the second semiconductor area.

8. The image sensing device of claim 1, further comprising a planarization layer disposed on the substrate layer,
wherein the planarization layer fills the trench.

9. The image sensing device of claim 8, further comprising: an insulating layer disposed on the planarization layer; a deep trench recessed into the substrate layer in the thickness direction, the deep trench having a greater recess depth than the trench surrounding the active area; and a filling part disposed in the deep trench.

10. The image sensing device of claim 9, wherein an insulating layer is disposed in the deep trench, and
the filling part is disposed between adjacent insulating layers.

11. The image sensing device of claim 10, wherein the image sensing device includes a plurality of pixels,
wherein each of the plurality of pixels includes a pixel area in which the photodetector is disposed, and
wherein the deep trench is disposed between the pixel areas of adjacent pixels.

12. The image sensing device of claim 9, wherein a recess depth of the deep trench is greater than a recess depth of the trench.

13. The image sensing device of claim 1, wherein the substrate layer includes a base layer including one or more materials, and a pattern layer disposed on the base layer.

14. The image sensing device of claim 13, wherein a refractive index of the pattern layer is smaller than a refractive index of the base layer.

15. The image sensing device of claim 13, further comprising a plurality of first recessed structures and a plurality of second recessed structures that are recessed into the substrate layer in the thickness direction of the substrate layer,
wherein the plurality of first recessed structures and the plurality of second recessed structures are defined by the pattern layer and expose the base layer,
wherein the trench is defined by the base layer and the pattern layer.

16. The image sensing device of claim 15, wherein the base layer is formed of silicon, and a pattern layer is formed of silicon oxide.

17. The image sensing device of claim 1, wherein the substrate layer includes at least one of silicon (Si) or a silicon (Si) compound.

18. A system for imagining a target object, comprising:
a light source configured to emit light toward a target object; and
a pixel array including: a pixel area including an active area configured to receive light reflected from the target object; and a non-pixel area around the pixel area,
wherein the pixel array includes:
a circuit layer;
a photodetector including an active area configured to detect light and disposed on the circuit layer; and
a substrate layer disposed on the photodetector,
wherein the substrate layer includes a trench surrounding the active area, a deep trench in the non-pixel area, the deep trench having a greater recess depth than the trench surrounding the active area, and a recessed structure inside the trench or between the deep trench and the trench, and
wherein the trench, the deep trench, and the recessed structure have different recess depths.

19. The system of claim 18, wherein the recess depth of the deep trench is greater than the recess depth of the trench, and
the recess depth of the trench is greater than the recess depth of the recessed structure.

20. The system of claim 19, wherein the photodetector includes a single photon avalanche diode.
